(19) United States
(12) Patent Application Publication
(10) Pub. No.: US 2025/0140762 A1
(43) Pub. Date: May 1, 2025

(54) DISPLAY DEVICE

(71) Applicant: SAMSUNG DISPLAY CO., LTD., YONGIN-SI (KR)

(72) Inventor: Heechul Lee, Yongin-si (KR)

(21) Appl. No.: 18/934,915

(22) Filed: Nov. 1, 2024

(30) Foreign Application Priority Data
Nov. 1, 2023 (KR) 10-2023-0149356

(51) Int. Cl. H01L 25/075; H01L 33/62

(52) U.S. Cl. CPC H01L 25/0753; H10H 20/857

(57) ABSTRACT

Provided is a display device comprising a substrate including a display area and a peripheral area arranged adjacent to the display area, a pixel arranged in the display area of the substrate, and a signal transmission line configured to transmit a signal to the pixel, wherein the signal transmission line includes a first line including a first contact portion and a first extension portion extending in a first direction from the first contact portion, and a second line including a second contact portion overlapping the first contact portion and a second extension portion extending in a direction opposite to the first direction from the second contact portion, and wherein the first line and the second line are electrically connected to each other through a contact hole in an area in which the first contact portion and the second contact portion overlap each other.

### CROSS-REFERENCE TO RELATED APPLICATION

This application is based on and claims priority under 35 U.S.C. § 119 to Korean Patent Application No. 10-2023-0149356, filed on Nov. 1, 2023, in the Korean Intellectual Property Office, the disclosure of which is incorporated by reference herein in its entirety.

### BACKGROUND

### 1. Field of Disclosure

The present disclosure generally relates to a display device. More particularly, the present disclosure relates to a display device having a structure of a contact portion of a signal transmission line.

### 2. Description of the Related Art

There are several ways to build and use display devices which may provide users with visual information. Liquid crystal display devices employ a liquid crystal layer to emit light, while inorganic light-emitting display devices use an inorganic light-emitting diode and organic light-emitting display devices use an organic light-emitting diode to emit light.

A peripheral area, where light for implementing images is not emitted, is disposed outside a display area where light-emitting diodes are arranged to provide images. Signal transmission lines for transmitting signals to pixels arranged in the display area may be arranged in the peripheral area.

### SUMMARY

One or more embodiments include a display device and may provide a structure of a contact portion of a signal transmission line.

Additional aspects will be set forth in part in the description which follows and, in part, will be apparent from the description, or may be learned by practice of the presented embodiments of the disclosure.

According to one or more embodiments, a display device includes a substrate having a display area and a peripheral area arranged adjacent to the display area, a plurality of pixels arranged in the display area of the substrate, and a plurality of signal transmission lines configured to transmit signals to the plurality of pixels, wherein each of the plurality of signal transmission lines includes: a first line having a first contact portion and a first extension portion, wherein the first extension portion extends in a first direction from the first contact portion, and a second line having a second contact portion and a second extension portion, wherein the second contact portion of the second line overlaps the first contact portion of the first line, and the second extension portion extends in a direction opposite to the first direction from the second contact portion, and wherein the first line and the second line are electrically connected to each other through a first contact hole positioned in an area in which the first contact portion and the second contact portion overlap each other, and the first extension portion of the first line includes a first recess portion.

The first recess portion of the first line may include a first recess portion that may not overlap the second line.

The first contact hole may include a plurality of sub-contact holes arranged, in a plan view, in a matrix form in the first direction and a second direction perpendicular to the first direction.

The first recess portion may include a plurality of sub-recess portions arranged, in a plan view, in a matrix form in the first direction and the second direction.

In a plan view, the first recess portion and the first contact hole may have a same shape as each other.

The first recess portion may be single through-hole penetrating through a portion of the first line in a thickness direction of the first line.

The first contact hole includes a plurality of contact hole in the area in which the first contact portion of the first line and the second contact portion of the second line overlap each other.

The first recess portion may include a plurality of recess portions arranged in the first direction.

The first recess portion may be a welding portion formed by a laser welding process.

The first recess portion may penetrate through a portion of the first line in a thickness direction of the first line.

An upper surface of the first contact portion of the first line may have a concave shape in a cross-sectional view.

The plurality of signal transmission lines may include a first signal transmission line and a second signal transmission line which is spaced apart from the first signal transmission line in a second direction perpendicular to the first direction, and the display device may further include a sacrificial line which is interposed between the first signal transmission line and the second signal transmission line, is electrically insulated from the plurality of pixels, and is configured to receive a third voltage which is different from a first voltage applied to the first signal transmission line and a second voltage applied to the second signal transmission line.

The third voltage may have a same polarity as the second voltage, and an absolute value of the third voltage may be greater than an absolute value of the second voltage.

The plurality of signal transmission lines may include a first signal transmission line and a second signal transmission line, and the plurality of signal transmission lines are spaced apart from each other in a second direction perpendicular to the first direction, a second contact hole is positioned in an area in which the first line of the second signal transmission line and the second line of the second signal transmission line overlap each other, the second contact hole is arranged in a third direction from the first contact hole which is positioned in an area in which the first line and the second line of the first signal transmission line overlap each other, and the third direction is interposed between the first direction and the second direction.

According to one or more embodiments, a display device comprises a substrate including a display area and a peripheral area arranged adjacent to the display area, a plurality of pixels arranged in the display area of the substrate, a plurality of signal transmission lines configured to transmit signals to the plurality of pixels, wherein each of the plurality of signal transmission lines includes a first signal transmission line and a second signal transmission line which is spaced apart from the first signal transmission line, and a sacrificial line which is electrically insulated from each of the plurality of pixels, wherein the sacrificial line is interposed between the first signal transmission line and the second signal transmission line, wherein a first voltage is applied to the first signal transmission line, and a second voltage is applied to the second signal transmission line, and a third voltage which is different from the first and second voltages is applied to the sacrificial line.

The first voltage has a polarity different from a polarity of the second voltage, and the third voltage has a same polarity as the second voltage, and an absolute value of the third voltage is greater than an absolute value of the second voltage.

Each of the plurality of signal transmission lines may include a first line having a first contact portion and a first extension portion extending in a first direction from the first contact portion, and a second line having a second contact portion and a second extension portion, wherein the second contact portion of the second line overlaps the first contact portion, and the second extension portion extends in a direction opposite to the first direction from the second contact portion, and the first line and the second line are electrically connected to each other through a contact hole positioned in an area in which the first contact portion of the first line and the second contact portion of the second line overlap each other.

The contact hole may include a plurality of contact holes positioned in the area in which the first contact portion and the second contact portion overlap each other.

Each of the plurality of contact holes may include a plurality of sub-contact holes that are arranged, in a plan view, in a matrix form in the first direction and in a second direction perpendicular to the first direction.

According to one or more embodiments, a display device comprises a substrate including a display area and a peripheral area arranged adjacent to the display area, a plurality of pixels arranged in the display area of the substrate, and a plurality of signal transmission lines configured to transmit signals to the plurality of pixels, wherein each of the plurality of signal transmission lines includes a first signal transmission line and a second signal transmission line which is spaced apart from the first signal transmission line in a first direction, wherein the first signal transmission line includes a first line and a second line, and the first signal transmission line extends in a second direction perpendicular to the first direction, the second signal transmission line includes a first line and a second line, and the second signal transmission line extends in the second direction, a first contact hole defined in the first signal transmission line is positioned in an area in which the first line and the second line of the first signal transmission line overlap each other, a second contact hole defined in the second signal transmission line is positioned in an area in which the first line and the second line of the second signal transmission line overlap each other, the second contact hole is arranged in a third direction from the first contact hole, and the third direction is interposed between the first direction and the second direction.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a display device according to an embodiment;

FIG. 2 is a cross-sectional view schematically illustrating a cross-section taken along line I-I′ in FIG. 1;

FIG. 3 is an enlarged diagram illustrating region A in FIG. 1, according to an embodiment;

FIG. 4 is a cross-sectional view schematically illustrating a cross-section taken along line II-II′ in FIG. 3;

FIG. 5 is an enlarged diagram illustrating region B in FIG. 4;

FIG. 6 is an enlarged diagram illustrating region A in FIG. 1, according to another embodiment;

FIG. 7 is a cross-sectional view schematically illustrating a cross-section taken along line III-III′ in FIG. 6;

FIG. 8 is an enlarged diagram illustrating region C in FIG. 7;

FIG. 9 is an enlarged diagram illustrating region A in FIG. 1, according to another embodiment;

FIG. 10 is a cross-sectional view schematically illustrating a cross-section taken along line IV-IV′ in FIG. 9;

FIG. 11 is an enlarged diagram illustrating region A in FIG. 1, according to another embodiment; and

FIG. 12 is an enlarged diagram illustrating region A in FIG. 1, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the present disclosure and a method for accomplishing them will be described more fully with reference to the accompanying drawings, in which one or more embodiments are shown. This disclosure may, however, be embodied in many different forms and should not be construed as limited to the embodiments set forth herein.

One or more embodiments will be described below in more detail with reference to the accompanying drawings. Those components that are the same or are in correspondence are rendered the same reference numeral regardless of the figure number, and redundant descriptions thereof are omitted.

In an embodiment below, terms such as “first” and “second” are used herein merely to describe a variety of elements, but the elements are not limited by the terms. Such terms are used only for the purpose of distinguishing one element from another element.

In an embodiment below, an expression used in the singular encompasses the expression of the plural, unless it has a clearly different meaning in the context.

In an embodiment below, terms such as “include” or “comprise” may be construed to denote a certain characteristic or element, or a combination thereof, but may not be construed to exclude the existence of or a possibility of addition of one or more other characteristics, elements, or combinations thereof.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.” In addition, “at least one of A and B” may include “A,” “B,” or “A and B.”

It will be understood that when a layer, region, or element is referred to as being “connected” to another layer, region, or element, it may be “directly connected” to the other layer, region, or element and/or may be “indirectly connected” to the other layer, region, or element with other layer, region, or element therebetween. For example, it will be understood that when a layer, region, or element is referred to as being “electrically connected” to another layer, region, or element, it may be “directly electrically connected” to the other layer, region, or element and/or may be “indirectly electrically connected” to other layer, region, or element with other layer, region, or element therebetween.

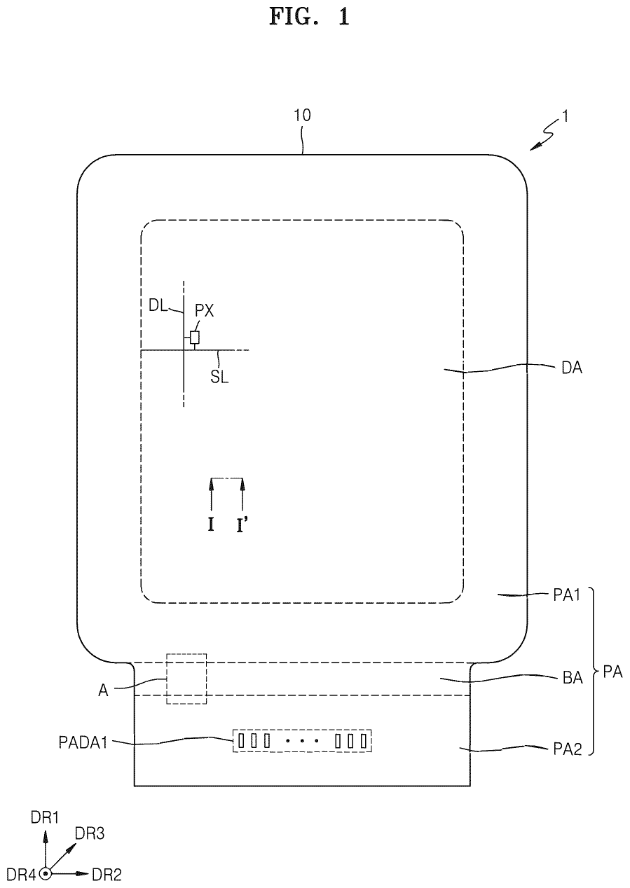

FIG. 1 is a plan view schematically illustrating a display device 1 according to an embodiment.

Referring to FIG. 1, the display device 1 may be used not only as a display screen of a portable electronic device such as mobile phones, smartphones, tablet personal computers (PCs), mobile communication terminals, electronic notebooks, electronic books, portable multimedia players (PMPs), navigations, or ultra mobile PCs (UMPCs), but also as a display screen of various products such as televisions, laptops, monitors, billboards, or Internet of Things (IoT). In addition, the display device 1 according to an embodiment may be used for a wearable device such as smartwatches, watch phones, glasses-type displays, or head-mounted displays (HMDs). In addition, the display device 1 according to an embodiment may be used as an instrumental panel of a vehicle, a center information display (CID) arranged on a center fascia or a dashboard of a vehicle, a room mirror display that replaces side-view mirrors of a vehicle, or a display screen arranged on a rear surface of a front seat as an entertainment for rear seats of a vehicle. For convenience of description, a case in which the display device 1 is used for a smartphone is described below.

When viewed in a direction perpendicular to one surface of the display device 1, the display device 1 may have an approximately rectangular shape. For example, as depicted in FIG. 1, the display device 1 may have an overall rectangular planar shape having a long side extending in a first direction (e.g., a DR1 direction) and a short side extending in a second direction (e.g., a DR2 direction). A corner at which the long side in the first direction and the short side in the second direction meet each other has a right-angled shape or a round shape with a certain curvature as depicted in FIG. 1. However, the planar shape of the display device 1 is not limited to a rectangle, and may include various shapes such as triangles, circles, ellipses, and any polygonal shapes.

The display device 1 may include a display area DA and a peripheral area PA disposed outside the display area DA.

The display device 1 may provide an image through an array of a plurality of pixels PX arranged two-dimensionally in rows and columns in the display area DA. Each pixel PX may include a pixel circuit and a light-emitting element driven by the pixel circuit. An image may be provided by light emitted by the light-emitting element of the pixel PX.

Because an area in which the image is provided is determined by an arrangement of a plurality of light-emitting elements, the display area DA may be defined by the plurality of light-emitting elements. In the display area DA, not only light-emitting elements and pixel circuits, but also various signal lines and power lines electrically connected to the pixel circuits may be arranged. For example, FIG. 1 shows a scan line SL and a data line DL as signal lines which are electrically connected to transistors included in the pixel PX.

The peripheral area PA may not provide an image and may entirely or partially surround the display area DA. Various lines and driving circuits may be arranged in the peripheral area PA to provide electrical signals or power to the display area DA.

The peripheral area PA may include a first peripheral area PA1 arranged outside the display area DA, a second peripheral area PA2 arranged on one side of the first peripheral area PA1, and a bending area BA interposed between the first peripheral area PA1 and the second peripheral area PA2 along the first direction. One portion of the peripheral area PA may extend in a direction away from the display area DA. In other words, the display device 1 may include a first area including the display area DA and the first peripheral area PA1 surrounding the display area DA and a second area extending in one direction from the first area. The second area may include the bending area BA and the second peripheral area PA2.

A portion of the display device 1 may be bent. The display device 1 may be bent with a certain curvature in the bending area BA. For example, when the display device 1 is bent in the bending area BA, the first area including the display area DA and the first peripheral area PA1 may face one surface of the second peripheral area PA2.

The first peripheral area PA1 may form a front surface of the display device 1 together with the display area DA. The front surface of the display device 1 may be a surface on which an image is displayed.

The second peripheral area PA2 may include a pad area PADA1 in which a plurality of pads are arranged. In the pad area PADA1, a display driving unit configured to receive control signals and power voltages and generate and output signals and voltages for driving the display device 1 may be arranged. The display driving unit may include an integrated circuit (IC).

The display device 1 may include a substrate 10 and various elements included in the display device 1 may be disposed on the substrate 10. For example, a plurality of light-emitting elements defining the display area DA, pixel circuits respectively driving the light-emitting elements, signal lines, and/or voltage lines configured to provide electrical signals and/or voltages to the respective pixel circuits and driving circuits may be disposed on the substrate 10.

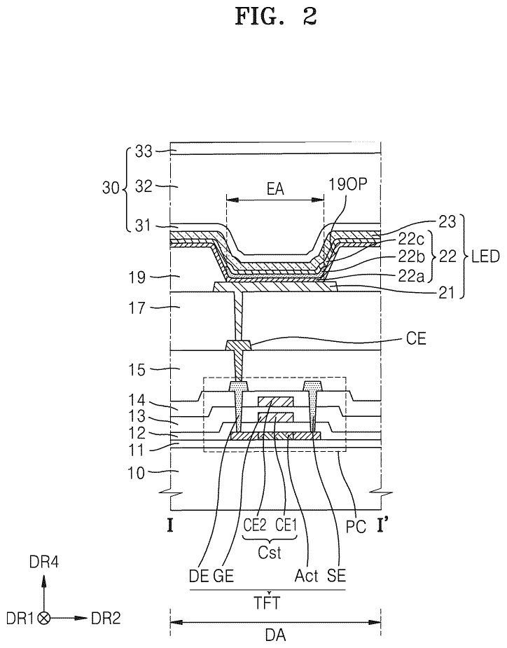

FIG. 2 is a cross-sectional view schematically illustrating a cross-section taken along line I-I′in FIG. 1. FIG. 2 shows a portion of a cross-section of the display device 1 arranged in the display area DA.

Referring to FIG. 2, the display device 1 may include the substrate 10, a light-emitting element LED disposed on the substrate 10, and an encapsulation member 30 disposed on the light-emitting element LED.

The substrate 10 may include glass or polymer resin. The polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, etc. The substrate 10 including polymer resin may have flexible, rollable, or bendable properties. The substrate 10 may have a multi-layer structure including a layer having the polymer resin described above and an inorganic layer (not shown herein). The substrate 10 may have the display area DA and the peripheral area PA arranged adjacent to the display area DA.

A buffer layer 11 may be positioned on the substrate 10 to reduce or block permeation of foreign substances, moisture, or ambient air which penetrates from a lower portion of the substrate 10, and may provide a flat surface to a semiconductor layer Act. The buffer layer 11 may include an inorganic material such as an oxide or a nitride, an organic material, or an organic/inorganic composite, and may have a single-layer or multi-layer structure of an inorganic material or/and an organic material. A barrier layer for blocking ambient air permeation may be further included between the substrate 10 and the buffer layer 11.

A pixel circuit PC including a thin-film transistor TFT and a storage capacitor Cst may be disposed on the buffer layer 11. The thin-film transistor TFT may include a drain electrode DE, a source electrode SE, the semiconductor layer Act interposed between the source electrode SE and the drain electrode DE, and a gate electrode GE overlapping the semiconductor layer Act along a thickness direction (i.e., fourth direction DR4).

The semiconductor layer Act may be disposed on the buffer layer 11 and may include polysilicon. In one example, the semiconductor layer Act may include amorphous silicon. In another example, the semiconductor layer Act may include an oxide of at least one material selected from the group consisting of indium (In), gallium (Ga), tin (Sn), zirconium (Zr), vanadium (V), hafnium (Hf), cadmium (Cd), germanium (Ge), chrome (Cr), titanium (Ti), and zinc (Zn). The semiconductor layer Act includes a channel region corresponding to the semiconductor layer Act, and a source region corresponding to the source electrode SE and a drain region corresponding to the drain electrode DE, which are doped with impurities. The source region may be arranged at opposite side of the drain region with respect to the channel region.

A first gate insulating layer 12 may be disposed on the buffer layer 11 and the semiconductor layer ACT and overlap the semiconductor layer Act in the thickness direction. The first gate insulating layer 12 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 12 may be a single layer or multi-layer including the inorganic insulating material described above.

The gate electrode GE may be disposed on the first gate insulating layer 12 to overlap the semiconductor layer Act in the thickness direction. The gate electrode GE may include molybdenum (Mo), aluminum (Al), copper (Cu), titanium (Ti), etc., and has a single layer or a multi-layer. For example, the gate electrode GE may be a single Mo layer.

A second gate insulating layer 13 may be disposed on the first gate insulating layer 12 and the gate electrode GE and overlaps the gate electrode GE in the thickness direction. The second gate insulating layer 13 may include an inorganic insulating material such as SiO₂, SiNₓ, SiON, Al₂O₃, TiO₂, Ta₂O₅, HfO₂, or ZnO₂. The second gate insulating layer 13 may be a single layer or multi-layer including the inorganic insulating material described above.

A second capacitor electrode CE2 of the storage capacitor Cst may be disposed on the second gate insulating layer 13. The second capacitor electrode CE2 may overlap the gate electrode GE in the thickness direction. The gate electrode GE and the second capacitor electrode CE2 may form the storage capacitor Cst by overlapping each other with respect to the second gate insulating layer 13 disposed therebetween. In this case, the gate electrode GE may function as a first capacitor electrode CE1 of the storage capacitor Cst.

The second capacitor electrode CE2 may include Al, platinum (Pt), palladium (Pd), silver (Ag), magnesium (Mg), gold (Au), nickel (Ni), neodymium (Nd), iridium (Ir), Cr, calcium (Ca), Mo, Ti, tungsten (W), and/or Cu, and has a single layer or multi-layer of the material described above.

An interlayer insulating layer 14 may be disposed on the second gate insulating layer 13 and the second capacitor electrode CE2 and overlap the second capacitor electrode CE2 in the thickness direction. The interlayer insulating layer 14 may include SiO₂, SiNₓ, SiON, Al₂O₃, TiO₂, Ta₂O₅, HfO₂, or ZnO₂. The interlayer insulating layer 14 may be a single layer or multi-layer including the inorganic insulating material described above.

The source electrode SE and the drain electrode DE may be disposed on the interlayer insulating layer 14, and penetrates through the first gate insulating layer 12, second gate insulating layer 13, and the interlayer insulating layer 14 to in direct contact with the source region and the drain region of the semiconductor layer Act. Each of the source electrode SE and the drain electrode DE may include a conductive material, including Mo, Al, Cu, Ti, etc., and may be formed of a multi-layer or single layer including the material described above. For example, the source electrode SE and the drain electrode DE may have a multi-layer structure of Ti/Al/Ti. In another example, the source electrode SE or the drain electrode DE may be omitted. For example, adjacent thin-film transistors TFT may share the source region or the drain region of the semiconductor layer Act, and the source region or the drain region may function as the source electrode SE or the drain electrode DE.

A first planarization insulating layer 15 may be disposed on the interlayer insulating layer 14 to cover the source electrode SE and the drain electrode DE. A connection electrode CE may be disposed on the first planarization insulating layer 15. The connection electrode CE may be directly connected to the drain electrode DE penetrating through the first planarization insulating layer 15. However, in another example, the connection electrode CE may be directly connected to the source electrode SE. A second planarization insulating layer 17 may be disposed on the first planarization insulating layer 15 to cover the connection electrode CE. The second planarization insulating layer 17 may provide a flat surface to a pixel electrode 21 disposed thereon. The pixel electrode 21 may be connected to the connection electrode CE through penetrating the second planarization insulating layer 17. Thus, the pixel electrode 21 and the thin-film transistor TFT may be electrically connected to each other by the connection electrode CE. Herein, a planarization insulating layer may include two layers. However, in another example, the number of planarization insulating layers may be variously modified. Thus, the number of planarization insulating layer may be more or less than two layers.

The first and second planarization insulating layers 15 and 17 may include an organic material or an inorganic material and may have a single-layer structure or a multi- layer structure. The first and second planarization insulating layers 15 and 17 may include general-purpose polymers such as benzocyclobutene (BCB), polyimide, hexamethyldisiloxane (HMDSO), polymethylmethacrylate (PMMA), or polystyrene (PS), polymer derivatives having a phenol-based group, acryl-based polymers, imide-based polymers, aryl ether-based polymers, amide-based polymers, fluorine-based polymers, p-xylene-based polymers, vinyl alcohol-based polymers, etc. The first and second planarization insulating layers 15 and 17 may include an inorganic insulating material such as SiO₂, SiNₓ, SiON, Al₂O₃, TiO₂, Ta₂O₅, HfO₂, or ZnO₂. When forming the first and second planarization insulating layers 15 and 17, after a layer is formed, chemical mechanical polishing may be performed on an upper surface of that layer to provide a flat upper surface.

The light-emitting element LED may be disposed on the second planarization insulating layer 17. The light-emitting element LED may include the pixel electrode 21, an intermediate layer 22 disposed on the pixel electrode 21, and an opposite electrode 23 disposed on the intermediate layer 22 in the thickness direction.

The pixel electrode 21 may be disposed on the second planarization insulating layer 17. The pixel electrode 21 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 21 may include a reflective film including Ag, Mg, Al, Pt, Pd, Au, Ni, Nd, Ir, Cr, or a compound thereof. For example, the pixel electrode 21 may have a structure having films formed of ITO, IZO, ZnO, or In₂O₃, over/under the reflective film described above. In this case, the pixel electrode 21 may have a stacked structure of ITO/Ag/ITO.

A pixel-defining layer 19 may be disposed on the second planarization insulating layer 17 to cover an edge of the pixel electrode 21, and a pixel opening 19OP through which a central portion of the pixel electrode 21 is exposed is defined in the pixel-defining layer 19. A size and shape of an emission area EA of the light-emitting element LED (i.e., pixel) when viewed from a plan may be defined by the pixel opening 19OP.

The pixel-defining layer 19 may increase a distance between an edge of the pixel electrode 21 and the opposite electrode 23 disposed on the pixel-defining layer 19 so that it prevents an arc or the like from occurring at an edge of the pixel electrode 21.

The pixel-defining layer 19 may include an organic insulating material such as polyimide, polyamide, acrylic resin, BCB, HMDSO, and phenolic resin and may be formed by a spin coating process.

In an embodiment, the pixel-defining layer 19 may further include a light-blocking material (not shown herein). The light-blocking material may include carbon black, carbon nanotubes, resin or paste containing black dye, metal particles, for example, Ni, Al, Mo, and an alloy thereof, metal oxide particles (e.g., chrome oxide), or metal nitride particles (e.g., chrome nitride). When the pixel-defining layer 19 includes a light-blocking material, external reflection caused by metal structures disposed under the pixel-defining layer 19 may be reduced.

The intermediate layer 22 may be interposed between the pixel electrode 21 and the opposite electrode 23. The intermediate layer 22 may include a first functional layer 22a, an emission layer 22b disposed on the first functional layer 22a, and a second functional layer 22c disposed on the emission layer 22b in the thickness direction.

The emission layer 22b formed to correspond to the pixel-defining layer 19 may be arranged in the pixel opening 19OP of the pixel-defining layer 19. The emission layer 22b may include a polymer material or a low-molecular weight material, and emits red, green, blue, or white light.

The first functional layer 22a may be disposed below the emission layer 22b, and the second functional layer 22c may be disposed over the emission layer 22b. In an embodiment, unlike the emission layer 22b being patterned and arranged for each pixel, the first functional layer 22a and the second functional layer 22c may be integrally provided across the entire surface of the display area DA. That is, the emission layer 22b may overlap the emission area EA of the light-emitting element LED in the thickness direction

The first functional layer 22a may be a single layer or a multi-layer. For example, when the first functional layer 22a is formed of a polymer material, the first functional layer 22a is a hole transport layer, which is a single-layer structure, and may be formed of poly-(3,4)-ethylene-dihydroxythiophene (PEDOT) or polyaniline (PANI). When the first functional layer 22a is formed of a low-molecular weight material, the first functional layer 22a may include a hole injection layer and a hole transport layer.

The second functional layer 22c may be optionally arranged. For example, when the first functional layer 22a and the emission layer 22b are formed of a polymer material, the second functional layer 22c may be formed. The second functional layer 22c may be a single layer or a multi-layer. The second functional layer 22c may include an electron transport layer and/or an electron injection layer. In another example, at least one of a hole injection layer, a hole transport layer, an electron transport layer, and an electron injection layer may be omitted.

The opposite electrode 23 may include a conductive material having a relatively low work function. For example, the opposite electrode 23 may include a (semi-) transparent layer having Ag, Mg, Al, Ni, Cr, Li, Ca, or an alloy thereof. Alternatively, the opposite electrode 23 may further include a layer including an ITO, IZO, ZnO, or In₂O₃, on the (semi-) transparent layer having the materials described above. In an embodiment, the opposite electrode 23 may include Ag and Mg.

In an embodiment, a capping layer (not shown herein) may be disposed on the light-emitting element LED. The capping layer may improve emission efficiency of the light-emitting element LED based on the principle of constructive interference. The capping layer may be an organic capping layer including an organic material, an inorganic capping layer including an inorganic material, or a composite capping layer including an organic material and an inorganic material.

The encapsulation member 30 may be disposed on the light-emitting element LED. The encapsulation member 30 may encapsulate the light-emitting element LED. In an embodiment, the encapsulation member 30 may include at least one inorganic encapsulation layer and at least one organic encapsulation layer. For example, the encapsulation member 30 may include first and second inorganic encapsulation layers 31 and 33 and an organic encapsulation layer 32 interposed therebetween.

Each of the first and second inorganic encapsulation layers 31 and 33 may include one or more inorganic insulating materials. The inorganic insulating materials may include Al₂O₃, TiO₂, Ta₂O₅, HfO₂, ZnO, SiOₓ, SiNₓ, or/and SiON. The first and second inorganic encapsulation layers 31 and 33 may be formed through chemical vapor deposition. However, the first and second inorganic encapsulation layers 31 and 33 may be formed through other deposition processes such as physical vapor deposition.

The organic encapsulation layer 32 may further include polyethylene terephthalate, polyethylene naphthalate, polycarbonate, polyimide, polyethylene sulfonate, polyoxymethylene, polyarylate, HMDSO, acryl-based resin, or a combination thereof.

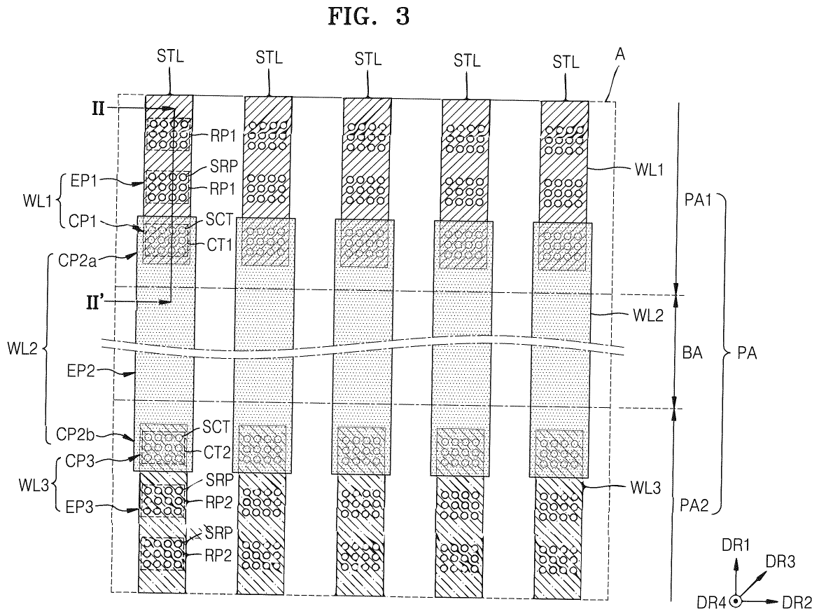

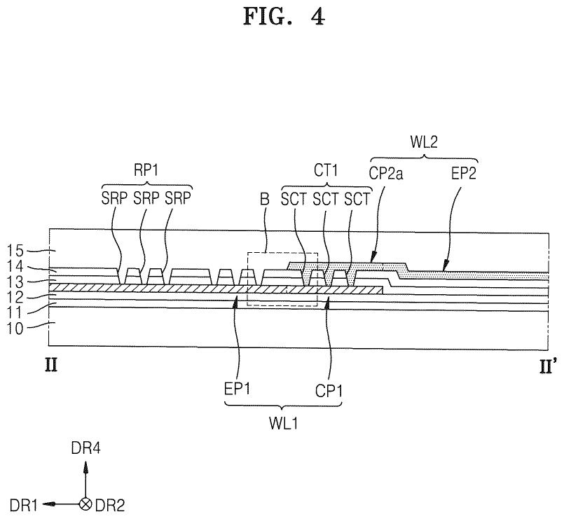

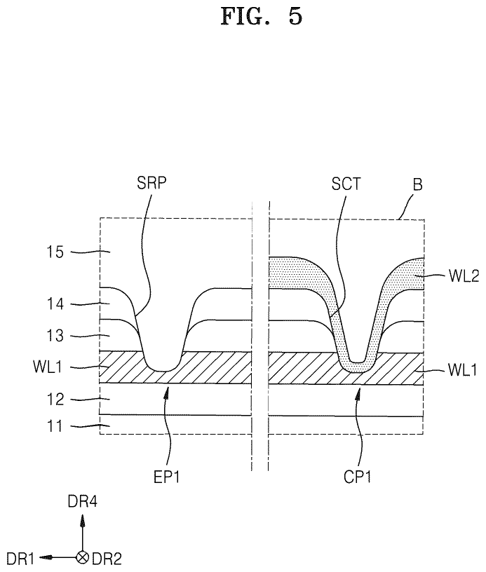

FIG. 3 is an enlarged diagram illustrating region A in FIG. 1, according to an embodiment. FIG. 4 is a cross-sectional view schematically illustrating a cross-section taken along line II-II′ in FIG. 3. FIG. 5 is an enlarged diagram illustrating region B in FIG. 4.

Referring to FIGS. 3 to 5, the display device 1 may include a plurality of signal transmission lines STL arranged on the peripheral area PA. The signal transmission lines STL may be configured to transmit signals to the pixels PX (See FIG. 1) arranged in the display area DA. The signal transmission lines STL may be electrically connected to signal lines or power lines arranged in the display area DA. For example, the signal transmission lines STL may be lines electrically connected to the scan lines SL (see FIG. 1) or the data lines DL (see FIG. 1) arranged in the display area DA.

The signal transmission lines STL may include a plurality of signal transmission lines in the peripheral area PA. The plurality of signal transmission lines STL may extend in the first direction (e.g., the DR1 direction) and may be arranged spaced apart from each other in the second direction (e.g., the DR2 direction) crossing the first direction (e.g., the DR1 direction). The signal transmission lines STL may include a first line WL1, a second line WL2, and a third line WL3. The first line WL1, the second line WL2, and the third line WL3 provided in each of the signal transmission lines STL may be electrically connected to each other and configured to transmit one signal.

The first line WL1 may be arranged in the first peripheral area PA1. The first line WL1 may include a first contact portion CP1 and a first extension portion EP1 extending from the first contact portion CP1 in the first direction (e.g., the DR1 direction). The first contact portion CP1 of the first line WL1 may overlap an upper portion of the second line WL2.

The second line WL2 may include a second-first contact portion CP2a, a second-second contact portion CP2b, and a second extension portion EP2 interposed between the second-first contact portion CP2a and the second-second contact portion CP2b. The second-first contact portion CP2a of the second line WL2 may overlap a lower portion of the first line WL1. The second-first contact portion CP2a of the second line WL2 may overlap the first contact portion CP1 of the first line WL1. The second-second contact portion CP2b of the second line WL2 may overlap an upper portion of the third line WL3. The second-second contact portion CP2b of the second line WL2 may overlap a third contact portion CP3 of the third line WL3. The second extension portion EP2 of the second line WL2 may extend in a direction opposite to the first direction (e.g., the DR1 direction) (e.g., a −DR1 direction). The second extension portion EP2 of the second line WL2 may be disposed between the second-first contact portion CP2a and the second-second contact portion CP2b. The second extension portion EP2 may extend in a direction opposite to the first direction DR1 from the second-first contact portion CP2a.

A middle portion of the second line WL2 may be arranged in the bending area BA. An upper portion of the second line WL2 may be arranged in the first peripheral area PA1, and a lower portion of the second line WL2 may be arranged in the second peripheral area PA2. In this case, the second extension portion EP2 of the second line WL2 may be arranged in the bending area BA. The second-first contact portion CP2a of the second line WL2 may be disposed in the first peripheral area PA1 to overlap the first line WL1.

The second-second contact portion CP2b of the second line WL2 may be disposed in the second peripheral area PA2 to overlap the third line WL3.

The third line WL3 may be arranged in the second peripheral area PA2. The third line WL3 may include the third contact portion CP3 and a third extension portion EP3 that extends in a direction opposite to the first direction (e.g., the DR1 direction) (e.g., the −DR1 direction) from the third contact portion CP3. The third contact portion CP3 of the third line WL3 may overlap the second line WL2.

In an embodiment, the second line WL2 may be disposed on the first line WL1. In an embodiment, the third line WL3 may be arranged on the same layer on which the first line WL1 may be arranged. That is, the second line WL2 may be disposed over the first line WL1 and the third line WL3. However, one or more embodiments are not limited thereto.

In an embodiment, as depicted in FIG. 5, the first line WL1 may be arranged between the first gate insulating layer 12 and the second gate insulating layer 13 in the thickness direction (i.e. fourth direction DR4). For example, the first line WL1 may be arranged on the same layer on which the gate electrode GE is arranged. In an embodiment, as depicted in FIG. 4, the second line WL2 may be interposed between the interlayer insulating layer 14 and the first planarization insulating layer 15. For example, the second line WL2 may be disposed on the same layer on which the drain electrode DE or the source electrode SE is arranged. In an embodiment, similar to the first line WL1, the third line WL3 may be interposed between the first gate insulating layer 12 and the second gate insulating layer 13 in the thickness direction (i.e. fourth direction DR4). However, a stacked structure of the first to third lines WL1, WL2, and WL3 is not limited thereto, and is variously modified. For example, the first line WL1 may be arranged on the same layer on which the second capacitor electrode CE2 may be arranged, and the second line WL2 may be arranged on the same layer on which the connection electrode CE is arranged.

The first line WL1, the second line WL2, and the third line WL3 may be electrically connected to each other. The first line WL1 and the second line WL2 may be electrically connected to each other through a first contact hole CT1 in an area in which the first contact portion CP1 of the first line WL1 and the second-first contact portion CP2a of the second line WL2 overlap each other. In an embodiment, as depicted in FIG. 4, the first contact hole CT1 may penetrate through the second gate insulating layer 13 and the interlayer insulating layer 14 in the thickness direction (i.e. fourth direction DR4). Although not shown herein, the second line WL2 and the third line WL3 may be electrically connected to each other through a second contact hole CT2 in an area in which the second-second contact portion CP2b of the second line WL2 and the third contact portion CP3 of the third line WL3 overlap each other. In an embodiment, similar to the first contact hole CT1, the second contact hole CT2 may penetrate through the second gate insulating layer 13 and the interlayer insulating layer 14 in the thickness direction (i.e. fourth direction DR4).

Each of the first contact hole CT1 and the second contact hole CT2 may include a plurality of sub-contact holes SCT arranged in a matrix form in the first direction (e.g., the DR1 direction) and in the second direction (e.g., the DR2 direction) in a plan view. In an embodiment, the first contact hole CT1 and the second contact hole CT2 may be referred to as a first welding portion formed by laser welding. FIG. 5 shows that the first line WL1 and the second line WL2 are electrically connected to each other by the sub-contact hole SCT. In an embodiment, as depicted in FIG. 5, an upper surface of the first contact portion CP1 of the first line WL1 may have a concave shape due to the sub-contact hole SCT. The second line WL2 may be disposed on the sub-contact hole SCT, and the sub-contact hole SCT may expose an upper surface of the first line WL1. However, in another example, the sub-contact hole SCT may expose an upper surface of the first gate insulating layer 12 by penetrating through the first line WL1 in the thickness direction (e.g., a DR4 direction) of the first line WL1.

The first extension portion EP1 of the first line WL1 may include a first recess portion RP1. The first recess portion RP1 may not overlap the second line WL2 in the thickness direction. In an embodiment, the first recess portion RP1 may have substantially the same shape as the first contact hole CT1. For example, similar to a plurality of sub- contact holes SCT of the first contact hole CT1, the first recess portion RP1 may include a plurality of sub-recess portions SRP arranged in a matrix form in the first direction (e.g., the DR1 direction) and in the second direction (e.g., the DR2 direction) in a plan view. For example, as depicted in FIG. 4, each of the plurality of sub-recess portions SRP of the first recess portion RP1 may penetrate through the second gate insulating layer 13 and the interlayer insulating layer 14. In an embodiment, the first recess portion RP1 may be referred to as a second welding portion formed by laser welding. In an embodiment, as depicted in FIG. 5, an upper surface of the first extension portion EP1 of the first line WL1 may have a concave shape due to the sub-recess portion SRP. In FIG. 5, the sub-recess portion SRP may expose an upper surface of the first line WL1. However, in another example, the sub-recess portion SRP may expose the upper surface of the first gate insulating layer 12 by penetrating through the first line WL1 in the thickness direction (e.g., the DR4 direction) of the first line WL1.

Similar to the first line WL1, the third extension portion EP3 of the third line WL3 includes a second recess portion RP2. The second recess portion RP2 may not overlap the second line WL2. In an embodiment, the shape of the second recess portion RP2 may be substantially equal to the shape of the first contact hole CT1 or the second contact hole CT2. For example, the second recess portion RP2 includes a plurality of sub-recess portions SRP arranged in a matrix form in the first direction (e.g., the DR1 direction) and in the second direction (e.g., the DR2 direction) in a plan view. In an embodiment, the second recess portion RP2 may be formed by a laser welding process.

As depicted in FIG. 3, two first recess portions RP1 may be arranged in the first direction (e.g., the DR1 direction). However, in another example, the first recess portion RP1 may include one first recess portion or include a plurality of first recess portions. According to one or more embodiments, similar to the first recess portion RP1, the second recess portion RP2 may include one second recess portion or a plurality of second recess portions.

Due to the first recess portion RP1 of the first extension portion EP1 of the first line WL1, resistance of the first extension portion EP1 of the first line WL1 increases so that an increase in current due to ohmic contact where the first line WL1 and the second line WL2 meet each other may be prevented or minimized. Thus, corrosion where the first line WL1 and the second line WL2 overlap each other may be prevented or minimized. Similarly, due to the second recess portion RP2 of the third line WL3, corrosion where the second line WL2 and the third line WL3 overlap each other may be prevented or minimized.

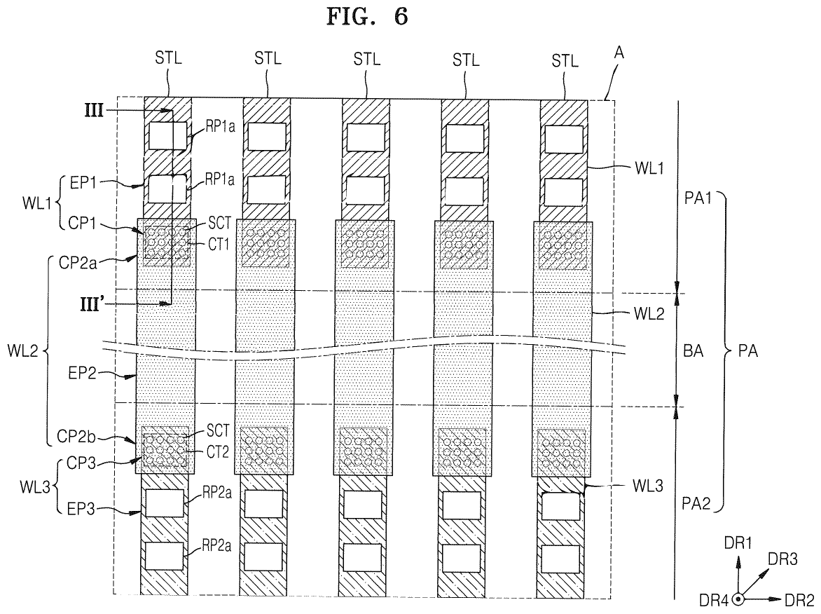

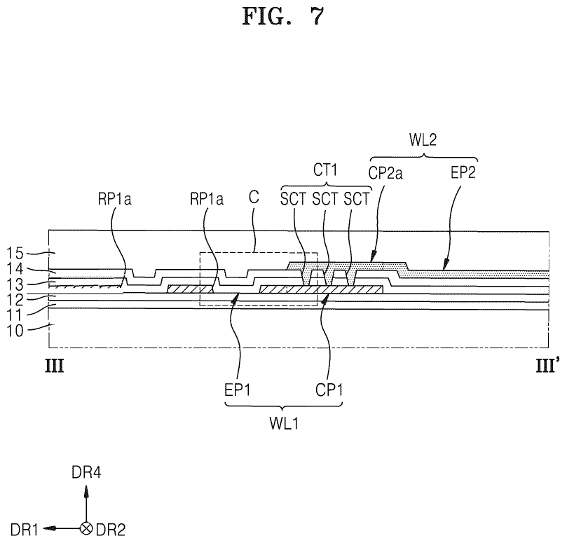

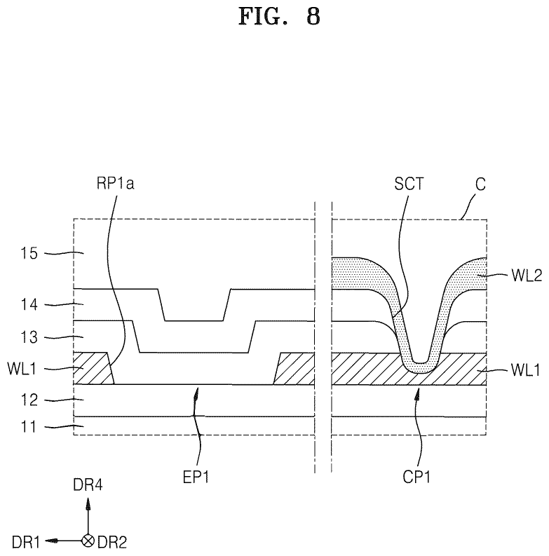

FIG. 6 is an enlarged diagram illustrating region A in FIG. 1, according to another embodiment. FIG. 7 is a cross-sectional view schematically illustrating a cross-section taken along line III-III′ in FIG. 6. FIG. 8 is an enlarged diagram illustrating region C in FIG. 7. FIGS. 6 to 8 are modifications of the embodiments described with reference to FIGS. 3 to 5 respectively, and differences from the embodiments of FIGS. 3 to 5 are mainly described, and redundant descriptions are omitted.

Referring to FIGS. 6 to 8, the first extension portion EP1 of the first line WL1 includes a plurality of first recess portions RP1a. Each of the first recess portions RP1a may not overlap the second line WL2. Each of the first recess portions RP1a may be single through-hole penetrating through a portion of the first line WL1 in the thickness direction (e.g., the DR4 direction) of the first line WL1. Each of the first recess portions RP1a may be a through-hole formed by removing a portion of the first line WL1. The plurality of first recess portions RP1a of the first line WL1 may be formed through, for example, an etching process.

As depicted in FIGS. 7 and 8, the second gate insulating layer 13 and the interlayer insulating layer 14 may overlap the first recess portions RP1a in the thickness direction. For example, while the second gate insulating layer 13 may be not arranged in the first contact hole CT1, the second gate insulating layer 13 may be arranged in the first recess portions RP1a.

When viewed from a plan, each of the first recess portions RP1a may have a shape or size different from a shape or size of the first contact hole CT1. For example, unlike the first contact hole CT1 having the plurality of sub-contact holes SCT arranged in a matrix form, each of the first recess portions RP1a may be single through-hole. For example, in a plan view, a size of the first recess portion RP1a of the first extension portion EP1 may be greater than a size of the sub-contact hole SCT of the first contact hole CT1.

In an embodiment, as depicted in FIGS. 7 and 8, the first extension portion EP1 of the first line WL1 may penetrate through the first line WL1 in the thickness direction (e.g., the DR4 direction) of the first line WL1 and may expose the upper surface of the first gate insulating layer 12. The second gate insulating layer 13 may be disposed on the first gate insulating layer 12 to cover the first recess portion RP1a of the first line WL1.

In an embodiment, due to the first recess portions RP1a of the first extension portion EP1 of the first line WL1, resistance of the first extension portion EP1 of the first line WL1 increases so that an increase in current due to ohmic contact where the first line WL1 and the second line WL2 meet each other may be prevented or minimized.

Similar to the first line WL1, the third extension portion EP3 of the third line WL3 may include a plurality of second recess portions RP2a. Each of the second recess portions RP2a may not overlap the second line WL2. Each of the second recess portions RP2a may be single through-hole passing through a portion of the third line WL3 in the thickness direction (e.g., the DR4 direction) of the third line WL3. Each of the second recess portions RP2a may be a through-hole formed by removing a portion of the third line WL3. Each of the second recess portions RP2a of the third line WL3 may be formed through, for example, an etching process.

As depicted in FIG. 8, an upper surface of the first contact portion CP1 of the first line WL1 may have a concave shape due to the sub-contact hole SCT. The second line WL2 may be disposed on the entirety of the sub-contact hole SCT and, the sub-contact hole SCT may expose an upper surface of the first line WL1. However, in another example, the sub-contact hole SCT may expose an upper surface of the first gate insulating layer 12 by penetrating through the first line WL1 in the thickness direction (e.g., a DR4 direction) of the first line WL1. Furthermore, the first recess portion RP1a of the first extension portion EP1 may expose side surfaces of the first line WL1.

Because the description of the structure of the second recess portion RP2a may be equally applicable to a structure of the first recess portion RP1a, redundant description for the second recess portion RP2a thereof is omitted.

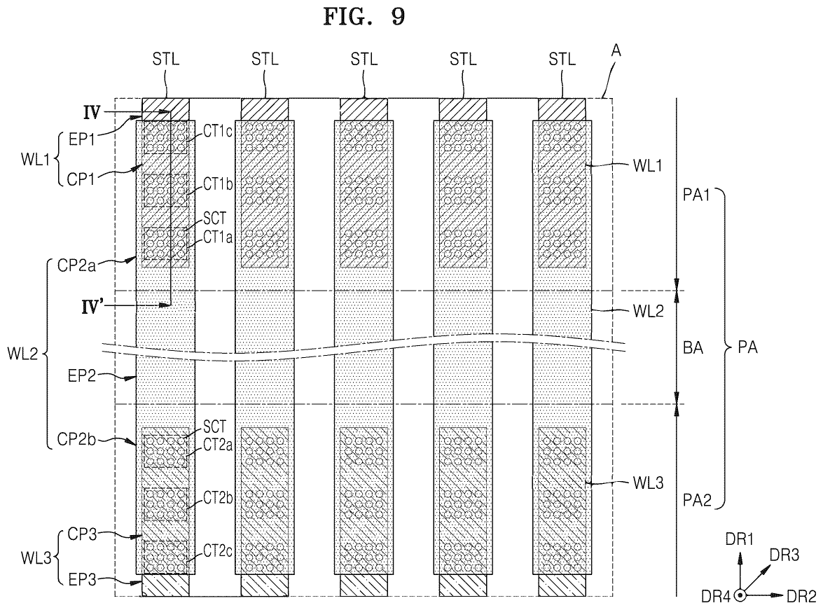

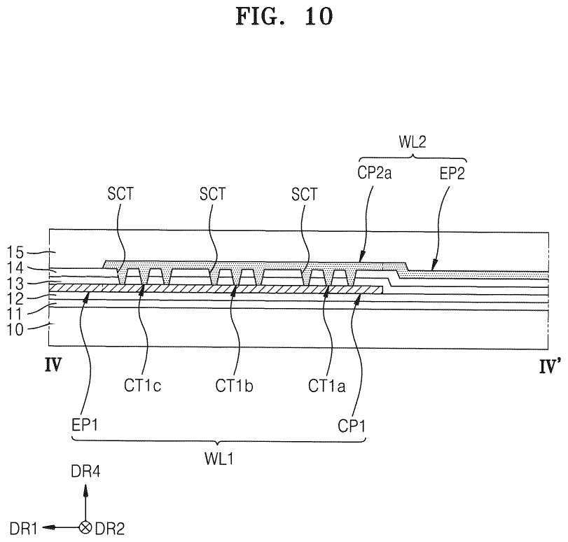

FIG. 9 is an enlarged diagram illustrating region A in FIG. 1, according to another embodiment. FIG. 10 is a cross-sectional view schematically illustrating a cross-section taken along line IV-IV′ in FIG. 9.

Referring to FIGS. 9 and 10, the first contact portion CP1 of the first line WL1 and the second-first contact portion CP2a of the second line WL2 may overlap each other where the plurality of first contact holes CT1a, CT1b, and CT1c are disposed. For example, the plurality of first contact holes CT1a, CT1b, and CT1c may be arranged in the first direction (e.g., the DR1 direction). Similarly, the third contact portion CP3 of the third line WL3 and the second-second contact portion CP2b of the second line WL2 may overlap each other where the plurality of second contact holes CT2a, CT2b, and CT2care disposed. For example, the plurality of second contact holes CT2a, CT2b, and CT2c may be arranged in the first direction (e.g., the DR1 direction). In this case, the second line WL2 may be disposed on each of the first line WL1 and the third line WL3.

Each of the plurality of first contact holes CT1a, CT1b, and CT1c may include a plurality of sub-contact holes SCT arranged in a matrix form in the first direction (e.g., the DR1 direction) and in the second direction (e.g., the DR2 direction) in a plan view. Similarly, each of the plurality of second contact holes CT2a, CT2b, and CT2c may include a plurality of sub-contact holes SCT arranged in a matrix form in the first direction (e.g., the DR1 direction) and in the second direction (e.g., the DR2 direction) in a plan view. In this case, the second line WL2 may be connected to the first line WL1 and the third line WL3 through the plurality of sub-contact holes.

In addition, as depicted in FIG. 9, each of the plurality of first contact holes CT1a, CT1b, and CT1c and the plurality of second contact holes CT2a, CT2b, and CT2c may include three contact holes. However, in another example, the number of the plurality of first contact holes CT1a, CT1b, and CT1c and the number of the plurality of second contact holes CT2a, CT2b, and CT2c may be variously modified. That is, the number of first contact holes CT1a, CT1b, and CT1c and the number of the plurality of second contact holes CT2a, CT2b, and CT2c may be more or less than three.

Because the signal transmission line STL may include the plurality of first contact holes CT1a, CT1b, and CT1c where the first line WL1 and the second line WL2 meet each other, ohmic contact where the first line WL1 and the second line WL2 meet each other are distributed so that corrosion due to an increase in current may be prevented or minimized. Similarly, because the signal transmission line STL includes the plurality of second contact holes CT2a, CT2b, and CT2c where the second line WL2 and the third line WL3 meet each other, corrosion of the lines due to an increase in current may be prevented or minimized.

According to the embodiment of FIGS. 9 and 10, the structure including the plurality of first contact holes CT1a, CT1b, and CT1c and/or the plurality of second contact holes CT2a, CT2b, and CT2c may be further applicable to an embodiment described with reference to FIGS. 3 to 5 or an embodiment described with reference to FIGS. 6 to 8.

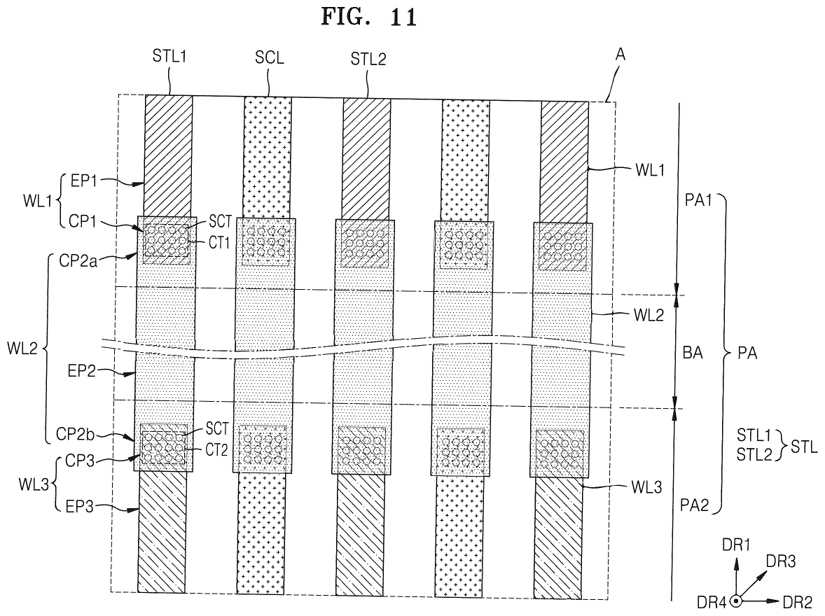

FIG. 11 is an enlarged diagram illustrating region A in FIG. 1, according to another embodiment.

Referring to FIG. 11, the display device 1 may include a plurality of signal transmission lines STL having a first signal transmission line STL1 and a second signal transmission line STL2. Each of the plurality of signal transmission lines STL may extend in the first direction (e.g., the DR1 direction) and may be spaced apart from each other in the second direction (e.g., the DR2 direction).

The first signal transmission line STL1 and the second signal transmission line STL2 may transmit different signals from each other. Each of the first signal transmission line STL1 and the second signal transmission line STL2 may include the first line WL1, the second line WL2, and the third line WL3. The first line WL1, the second line WL2, and the third line WL3 provided in each of the first signal transmission line STL1 and the second signal transmission line STL2 may be electrically connected to one another to transmit one signal.

The display device 1 may further include a sacrificial line SCL interposed between the first signal transmission line STL1 and the second signal transmission line STL2 along the second direction. That is, the sacrificial line SCL may be spaced apart from each of the first signal transmission line STL1 and the second signal transmission line STL2 in the second direction (e.g., the DR2 direction), and may extend in the first direction (e.g., the DR1 direction). However, unlike the first signal transmission line STL1 and the second signal transmission line STL2, the sacrificial line SCL may not transmit a signal to the pixel PX arranged in the display area DA. For example, the sacrificial line SCL may be electrically insulated from the pixel PX arranged in the display area DA.

In an embodiment, a first voltage may be applied to the first signal transmission line STL1, a second voltage may be applied to the second signal transmission line STL2, and a third voltage, which is different from the first voltage and the second voltage, may be applied to the sacrificial line SCL. In an embodiment, a first voltage applied to the first signal transmission line STL1 and a second voltage applied to the second signal transmission line STL2 may be voltages having different polarities from each other. In an embodiment, the second voltage applied to the second signal transmission line STL2 and the third voltage applied to the sacrificial line SCL may be voltages having the same polarity. For example, the first voltage may be a positive voltage, and the second voltage and the third voltage may be negative voltages. In an embodiment, an absolute value of the third voltage applied to the sacrificial line SCL may be greater than an absolute value of the second voltage applied to the second signal transmission line STL2.

The sacrificial line SCL may be arranged adjacent to the second signal transmission line STL2, and a magnitude of a DC voltage applied to the sacrificial line SCL may be greater than a magnitude of a DC voltage applied to the second signal transmission line STL2. Accordingly, electrons may be emitted from the sacrificial line SCL so that corrosion in the second signal transmission line STL2 adjacent to the sacrificial line SCL may be prevented. Similarly, the sacrificial line SCL, to which a voltage of the different polarity as the first signal transmission line STL1 may be applied, may be arranged adjacent to the first signal transmission line STL1 so that corrosion in the first signal transmission line STL1 may be prevented. For example, the sacrificial line SCL between the first signal transmission line STL1 and the second signal transmission line STL2 may emit electrons, reducing corrosion in both of the first signal transmission line STL1 and the second signal transmission lines STL2.

Similar to the embodiment described with reference to FIGS. 3 to 5 or the embodiment described with reference to FIGS. 6 to 8, in the embodiment of FIG. 11, a structure in which the first line WL1 includes the first recess portion RP1 or RP1a may be further applicable. Similar to the embodiment described with reference to FIGS. 9 and 10, in the embodiment of FIG. 11, a structure including a plurality of contact holes may be further applicable.

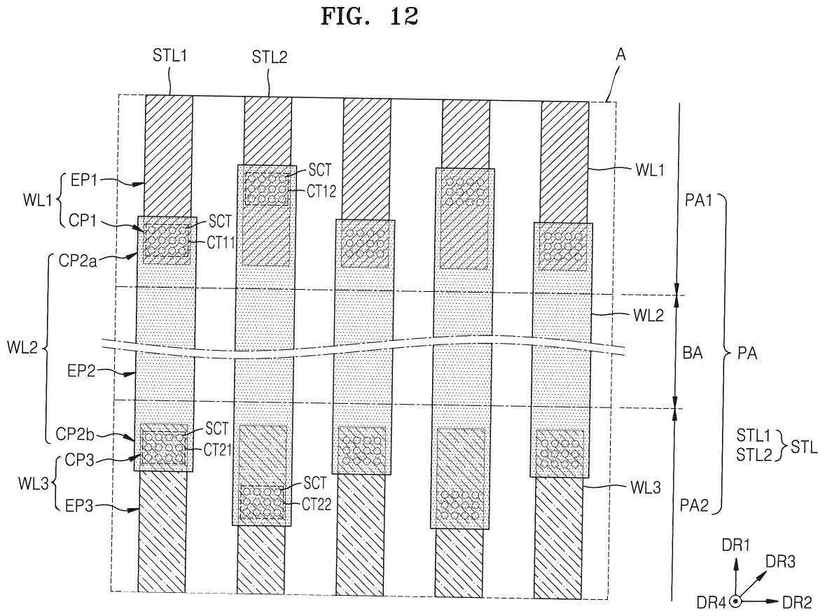

FIG. 12 is an enlarged diagram illustrating region A in FIG. 1, according to another embodiment.

Referring to FIG. 12, the display device 1 may include the plurality of signal transmission lines STL including the first signal transmission line STL1 and the second signal transmission line STL2. Each of the plurality of signal transmission lines STL may extend in the first direction (e.g., the DR1 direction). The plurality of signal transmission lines STL may be spaced apart from each other in the second direction (e.g., the DR2 direction).

The first signal transmission line STL1 and the second signal transmission line STL2 may transmit different signals from each other. Each of the first signal transmission line STL1 and the second signal transmission line STL2 may include the first line WL1, the second line WL2, and the third line WL3. The first line WL1, the second line WL2, and the third line WL3 provided in each of the first signal transmission line STL1 and the second signal transmission line STL2 may be electrically connected to one another to transmit one signal.

The first line WL1 and the second line WL2 of the first signal transmission line STL1 may be electrically connected to each other through a first-first contact hole CT11 where the first contact portion CP1 of the first line WL1 and the second-first contact portion CP2a of the second line WL2 overlap each other. The first-first contact hole CT11 may be positioned where the first line WL1 and the second line WL2 of the first signal transmission line STL1 meet. More particularly, the first-first contact hole CT11 may be positioned where the first contact portion CP1 and the second-first contact portion CP2a of the first signal transmission line STL1 meet. The second line WL2 and the third line WL3 of the first signal transmission line STL1 may be electrically connected to each other through a second-first contact hole CT21 where the third contact portion CP3 of the third line WL3 and the second-second contact portion CP2b of the second line WL2 overlap each other. The second-first contact hole CT21 may be positioned where the second line WL2 and the third line WL3 of the first signal transmission line STL1 meet. More particularly, the second-first contact hole CT21 may be positioned where the third contact portion CP3 and the second-second contact portion CP2b of the first signal transmission line STL1 meet.

The first line WL1 and the second line WL2 of the second signal transmission line STL2 may be electrically connected to each other through a first-second contact hole CT12 where the first contact portion CP1 of the first line WL1 and the second-first contact portion CP2a of the second line WL2 overlap each other. The first-second contact hole CT12 may be positioned where the first line WL1 and the second line WL2 of the second signal transmission line STL2 meet. More particularly, the first-second contact hole CT12 may be positioned where the first contact portion CP1 and the second-first contact portion CP2a of the second signal transmission line STL2 meet. In addition, the second line WL2 and the third line WL3 of the second signal transmission line STL2 may be electrically connected to each other through a second-second contact hole CT22 where the third contact portion CP3 of the third line WL3 and the second-second contact portion CP2b of the second line WL2 overlap each other. The second-second contact hole CT22 may be positioned where the second line WL2 and the third line WL3 of the second signal transmission line STL2 meet. More particularly, the second-second contact hole CT22 may be positioned where the third contact portion CP3 and the second-second contact portion CP2b of the second signal transmission line STL2 meet.

The first-second contact hole CT12 of the second signal transmission line STL2 may be arranged in the third direction (e.g., the DR3 direction) from the first-first contact hole CT11 of the first signal transmission line STL1, the third direction being between the first direction (e.g., the DR1 direction) and the second direction (e.g., the DR2 direction). For example, as depicted in FIG. 12, the first-second contact hole CT12 of the second signal transmission line STL2 may be arranged diagonally from the first-first contact hole CT11 of the first signal transmission line STL1.

The second-second contact hole CT22 of the second signal transmission line STL2 may be arranged in a fifth direction from the second-first contact hole CT21 of the first signal transmission line STL1, the fifth direction being between a direction opposite to the first direction (e.g., a −DR1 direction) and the second direction (e.g., the DR2 direction). For example, as depicted in FIG. 12, the second-second contact hole CT22 of the second signal transmission line STL2 may be arranged diagonally from the second-first contact hole CT21 of the first signal transmission line STL1.

Similar to the embodiment described with reference to FIGS. 3 to 5 or the embodiment described with reference to FIGS. 6 to 8, in the embodiment of FIG. 12, a structure in which the first line WL1 includes the first recess portion RP1 may be further applicable. Similar to the embodiment described with reference to FIGS. 9 and 10, in the embodiment of FIG. 12, a structure including a plurality of contact holes may be further applicable. FIG. 12 does not show the sacrificial electrode SCL, but the present disclosure is not limited thereto. For example, similar to the embodiment described with reference to FIG. 11, in the embodiment of FIG. 12, a structure including the sacrificial line SCL may be further applicable.

According to an embodiment, a display device with improved reliability may be provided by minimizing corrosion that occurs between lines in contact with each other. However, the scope of one or more embodiments is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a substrate having a display area and a peripheral area arranged adjacent to the display area;
a plurality of pixels arranged in the display area of the substrate; and
a plurality of signal transmission lines configured to transmit signals to the plurality of pixels,
wherein each of the plurality of signal transmission lines includes:
a first line having a first contact portion and a first extension portion, wherein the first extension portion extends in a first direction from the first contact portion; and
a second line having a second contact portion and a second extension portion, wherein the second contact portion of the second line overlaps the first contact portion of the first line, and the second extension portion extends in a direction opposite to the first direction from the second contact portion, and
wherein the first line and the second line are electrically connected to each other through a first contact hole positioned in an area in which the first contact portion and the second contact portion overlap each other, and
the first extension portion of the first line includes a first recess portion.

2. The display device of claim 1, wherein the first recess portion does not overlap the second line.

3. The display device of claim 1, wherein the first contact hole includes a plurality of sub-contact holes arranged, in a plan view, in a matrix form in the first direction and a second direction perpendicular to the first direction.

4. The display device of claim 3, wherein the first recess portion includes a plurality of sub-recess portions arranged, in a plan view, in a matrix form in the first direction and the second direction.

5. The display device of claim 3, wherein, in a plan view, the first recess portion and the first contact hole has a same shape as each other.

6. The display device of claim 3, wherein the first recess portion is single through-hole penetrating through a portion of the first line in a thickness direction of the first line.

7. The display device of claim 3, wherein the first contact hole includes a plurality of contact hole in the area in which the first contact portion of the first line and the second contact portion of the second line overlap each other.

8. The display device of claim 1, wherein the first recess portion includes a plurality of recess portions arranged in the first direction.

9. The display device of claim 1, wherein the first recess portion is a welding portion formed by a laser welding process.

10. The display device of claim 1, wherein the first recess portion penetrates through a portion of the first line in a thickness direction of the first line.

11. The display device of claim 1, wherein an upper surface of the first contact portion of the first line has a concave shape in a cross-sectional view.

12. The display device of claim 1, wherein the plurality of signal transmission lines includes a first signal transmission line and a second signal transmission line which is spaced apart from the first signal transmission line in a second direction perpendicular to the first direction, and
the display device further includes a sacrificial line which is interposed between the first signal transmission line and the second signal transmission line, is electrically insulated from the plurality of pixels, and is configured to receive a third voltage which is different from a first voltage applied to the first signal transmission line and a second voltage applied to the second signal transmission line.

13. The display device of claim 12, wherein the third voltage has a same polarity as the second voltage, and an absolute value of the third voltage is greater than an absolute value of the second voltage.

14. The display device of claim 1, wherein the plurality of signal transmission lines includes a first signal transmission line and a second signal transmission line, and the plurality of signal transmission lines are spaced apart from each other in a second direction perpendicular to the first direction,
a second contact hole is positioned in an area in which the first line of the second signal transmission line and the second line of the second signal transmission line overlap each other,
the second contact hole is arranged in a third direction from the first contact hole positioned in an area in which the first line and the second line of the first signal transmission line overlap each other, and
the third direction is interposed between the first direction and the second direction.

15. A display device comprising:
a substrate including a display area and a peripheral area arranged adjacent to the display area;
a plurality of pixels arranged in the display area of the substrate;
a plurality of signal transmission lines configured to transmit signals to the plurality of pixels, wherein each of the plurality of signal transmission lines includes a first signal transmission line and a second signal transmission line which is spaced apart from the first signal transmission line; and
a sacrificial line electrically insulated from the plurality of pixels, wherein the sacrificial line is interposed between the first signal transmission line and the second signal transmission line,
wherein a first voltage is applied to the first signal transmission line, and a second voltage is applied to the second signal transmission line, and
a third voltage which is different from the first and second voltages is applied to the sacrificial line.

16. The display device of claim 15, wherein the first voltage has a polarity different from a polarity of the second voltage, and
the third voltage has a same polarity as the second voltage, and an absolute value of the third voltage is greater than an absolute value of the second voltage.

17. The display device of claim 15, wherein each of the plurality of signal transmission lines includes:
a first line having a first contact portion and a first extension portion extending in a first direction from the first contact portion; and
a second line having a second contact portion and a second extension portion, wherein the second contact portion of the second line overlaps the first contact portion, and the second extension portion extends in a direction opposite to the first direction from the second contact portion, and
wherein the first line and the second line are electrically connected to each other through a contact hole positioned in an area in which the first contact portion of the first line and the second contact portion of the second line overlap each other.

18. The display device of claim 17, wherein the contact hole includes a plurality of contact holes positioned in the area in which the first contact portion of the first line and the second contact portion of the second line overlap each other.

19. The display device of claim 18, wherein each of the plurality of contact holes includes a plurality of sub-contact holes that are arranged, in a plan view, in a matrix form in the first direction and in a second direction perpendicular to the first direction.

20. A display device comprising:
a substrate including a display area and a peripheral area arranged adjacent to the display area;
a plurality of pixels arranged in the display area of the substrate; and
a plurality of signal transmission lines configured to transmit signals to the plurality of pixels, wherein each of the plurality of signal transmission lines includes a first signal transmission line and a second signal transmission line which is spaced apart from the first signal transmission line in a first direction,
wherein the first signal transmission line includes a first line and a second line, and the first signal transmission line extends in a second direction perpendicular to the first direction,
the second signal transmission line includes a first line and a second line, and the second signal transmission line extends in the second direction,
a first contact hole defined in the first signal transmission line is positioned in an area in which the first line and the second line of the first signal transmission line overlap each other,
a second contact hole defined in the second signal transmission line positioned in an area in which the first line and the second line of the second signal transmission line overlap each other,
the second contact hole is arranged in a third direction from the first contact hole, and
the third direction is interposed between the first direction and the second direction.
